(19) United States
(12) Patent Application Publication
(10) Pub. No.: US 2017/0194101 A1
(43) Pub. Date: Jul. 6, 2017

(54) HALIDE DOUBLE PEROVSKITE Cs2AgBiBr6 SOLAR-CELL ABSORBER HAVING LONG CARRIER LIFETIMES

(71) Applicant: The Board of Trustees of the Leland Stanford Junior University, Palo Alto, CA (US)

(72) Inventors: Hemamala Indivari Karunadasa, Palo Alto, CA (US); Adam H. Slavney, Stanford, CA (US)

(21) Appl. No.: 15/397,565

(22) Filed: Jan. 3, 2017

Related U.S. Application Data
(60) Provisional application No. 62/273,651, filed on Dec. 31, 2015.

(51) Int. Cl. H01G 9/20; H01L 27/28; H01L 51/44; H01L 51/42

(52) U.S. Cl. CPC H01G 9/2009; H01L 51/4206; H01L 51/4293; H01L 27/286; H01L 51/442; H01L 51/447; H01G 9/2027

(57) ABSTRACT

A solar-cell absorber layer for use in solar cells including tandem solar cells, is made of a metal-halide double perovskite material. The metal-halide double perovskite material has the formula A₂BB′X₆, where A is an inorganic cation, an organic cation, or a mixture of organic and inorganic cations where B and B′ are metals, and where X is a halide or a mixture of halides. For example, A can be Cs, Rb, K, Ba, CH₃NH₃, (NH₂)₂CH, or a mixture where B is Bi, Ag, Sn, In, Sb, Cu, Na, K, or Au of a predetermined oxidation state, and where B′ is Bi, Ag, Sn, In, Sb, Ga, Cu, or Au of various oxidation states, and where X is Br, I, Cl, F, or a mixture. One example of the metal-halide double perovskite material is Cs₂BiAgBr₆.

### RELATED APPLICATION

This application claims the benefit of Provisional Application No. 62/273,651 filed Dec. 31, 2015, the entire disclosure of which is incorporated herein by reference.

### FIELD

The present disclosure relates to solid-state solar cells. More particularly, the present disclosure relates to a halide double perovskite Cs₂AgBiBr₆ solar-cell absorber and solar cells constructed with such absorbers.

### BACKGROUND

A perovskite is the name of a family of compounds that share the same crystal structure (i.e., the atoms are arranged in the same way in the solid state). In the context of photovoltaics, the most studied perovskites are (CH₃NH₃)PbI₃ and (CH₃NH₃)PbBr₃. The three-dimensional (3D) hybrid perovskite RPbI₃ (where R=1+ ion such as CH₃NH₃⁺, (H₂N)₂CH⁺) has shown great promise as a solar-cell absorber with power-conversion efficiencies for single-junction devices increasing from 4% to 20% in just six years. However, the toxicity of lead is a primary concern for the wide-scale use of this technology, particularly in light of the water solubility of the material. The analogous tin perovskite (MA)SnI₃ (where MA=CH₃NH₃⁺) has been explored as a non-toxic alternative and efficiencies of devices employing these absorbers have reached approximately (ca.) 6%. However, the high-lying 5s orbitals of the Sn²⁺ centers render the perovskite unstable to oxidation, limiting the material's viability. Recently, several other nontoxic alternatives comprising zero- and two-dimensional structures have been explored, but a material with similar optoelectronic properties to (MA)PbI₃ has not yet been realized.

### SUMMARY

The perovskites (MA)PbX₃ (where MA=CH₃NH₃, and X=Br or I) have recently generated great interest as low-cost absorbers for high-efficiency solar cells. However, the toxicity of lead is a primary concern for the wide-scale use of this technology, particularly in light of the water solubility of the material. A material employing less toxic materials that show similar optoelectronic properties has not yet been realized. Disclosed herein is a novel double perovskite containing Bi′ which shows similar optoelectronic properties to (MA)PbI₃ while using considerably less toxic elements. The Bi containing material is also more stable to moisture and heat compared to (MA)PbX₃.

In order to replace Pb^{II} with in the Bi^{III} site of the A^{I}B^{II}X₃ (where X=halide) 3D perovskite structure, the material's charge neutrality has to be maintained by either introducing vacancies or by changing the oxidation state of the cations. According to one illustrative embodiment of the disclosure, Ag^{I} is used to form a double perovskite having the formula Cs₂Ag^{I}Bi^{III}Br₆. This material comprises one non-limiting example of a metal-halide double perovskite with Bi³⁺ ions according to the disclosure. A single-crystal X-ray structure of the material was obtained, which confirmed that it is an ordered double perovskite with Bi and Ag alternating in the B-sites (FIG. 1A). The Bi-based double perovskite (Cs₂AgBiBr₆) shows the characteristics of an indirect bandgap semiconductor with a shallow absorption region beginning at 1.8 eV followed by a sharp increase in absorption near 2.1 eV (FIG. 2A). Very long photoluminescence lifetimes were observed from Cs₂BiAgBr₆ (ca. 660 ns in powders, FIG. 2C), that are much longer than PL lifetimes from (MA)PbBr₃ films (170 ns) and approaches the unusually long lifetimes seen in optimized (MA)PbI₃ films (736 ns-1 μs). Long carrier recombination lifetimes are indicators of good photovoltaic performance. Although indirect bandgap semiconductors have longer PL lifetimes compared to direct bandgap materials, the long radiative lifetime in Cs₂BiAgBr₆ is unusual, especially for powders. Therefore, in various embodiments of the present disclosure, Cs₂BiAgBr₆ is used as a solar-cell absorber of a solar cell due to its long PL lifetime. In some embodiments, the Cs₂AgBiBr₆ solar-cell absorber can be used as a top (higher-bandgap) absorber in a tandem solar cell device. The band gap of 1.95 eV in Cs₂AgBiBr₆ is suitable for pairing with a bottom silicon solar-cell absorber (bandgap of 1.1 eV). Four- and two-terminal tandem cells with Si absorbers require higher-bandgap absorbers with ideal bandgaps of 1.8-2.0 eV and 1.8-1.9 eV, respectively.

Compared to (CH₃NH₃)PbI₃, the Bi-double perovskite of the present disclosure has many advantages. Bi is a nontoxic metal. In various embodiments of the Bi-double perovskite, Ag⁺ is used as the other B site cation. Although Ag⁺ can be toxic to humans, the solubility constant for AgBr (Kₛₚ at 25° C.=10⁻¹³) is approximately four orders of magnitude lower than for PbI₂, which reduces contamination risks. Substitution of different B-site cations for Ag in the double-perovskite architecture of the present disclosure can further reduce the material's toxicity. Further, the moisture sensitivity of (MA)PbI₃ is a serious problem for the material's large scale manufacture or long-term use. The Bi-based double perovskite of the present disclosure is stable to both humidity and light over at least 30 days (FIG. 3A). In addition, thermogravimetric analysis shows the Bi-based double perovskite is stable to mass loss up to ca. 350° C., while (CH₃NH₃)PbI₃ starts to lose volatile organic compounds at low temperatures. PXRD patterns obtained after heating Cs₂AgBiBr₆ at 100° C. in air for 72 h confirms structural integrity, while PXRD data of (MA)PbX₃ (X=Br and I) heated at 60° C. for 72 h in air show decomposition to PbX₂ (FIG. 3B). CsPbI₃ is more thermally stable than (CH₃NH₃)PbI₃, but CsPbI₃ does not form the 3D perovskite structure under ambient conditions. Typical solar cell operating temperatures are above 60° C., while temperatures above 100° C. are routinely used during solar-cell manufacture.

A solar cell, according to the present disclosure, comprises a solar-cell absorber layer made of a metal-halide double perovskite material.

In some embodiments, the solar cell comprises a hole-selective contact layer, an electron-selective contact layer, and first and second electrode layers.

In some embodiments of the solar cell, one of the first and second electrode layers, and the hole-selective contact layer are above the solar-cell absorber layer and the electron-selective contact layer and the other of the first and second electrode layers are below the solar-cell absorber layer.

In some embodiments of the solar cell, the metal-halide double perovskite material has the formula A₂BB′X₆, where A is an inorganic or organic cation, where B and B′ are metals, and where X is a halide.

In some embodiments of the solar cell, A is Cs, Rb, K, Ba, CH₃NH₃, or (NH₂)₂CH, where B is Bi, Ag, Sn, In, Sb, Cu, Na, K, or Au of a predetermined oxidation state, where B′ is Bi, Ag, Sn, In, Sb, Cu, Ga, or Au of various oxidation states, and where X is Br, I, Cl, or F.

In some embodiments of the solar cell, the metal-halide double perovskite material is Cs₂BiAgBr₆.

A tandem solar cell, according the present disclosure, comprises first and second solar cells of different types, wherein one of the first and second solar cells includes a first solar-cell absorber layer made of a metal-halide double perovskite material and wherein the other one of the first and second solar cells includes a second solar-cell absorber layer.

In some embodiments of the tandem solar cell, the first and second solar cells are mechanically stacked.

In some embodiment of the tandem solar cell, the one of the first and second solar cells including the first solar-cell absorber layer further includes a glass layer and first and second transparent electrode layers.

In some embodiments of the tandem solar cell, the glass and one of the first and second transparent electrode layers are over the first solar-cell absorber layer, the other one of the first and second transparent electrode layers is under the first solar-cell absorber layer, and the one of the first and second transparent electrode layers is under the glass layer.

In some embodiments of the tandem solar cell, the other one of the first and second solar cells further includes an emitter layer or a transparent electrode layer, and a contact layer.

In some embodiments of the tandem solar cell, the emitter layer or the transparent electrode layer is over the second solar-cell absorber and contact layers, and the contact layer is under the second solar-cell absorber layer.

In some embodiments of the tandem solar cell, the first and second solar cells are monolithically integrated.

In some embodiments, the tandem solar cell further comprises a tunnel junction/recombination layer for integrating the first and second solar-cell absorber layers.

In some embodiments, the tandem solar cell further comprises a transparent electrode over the first solar-cell absorber layer.

In some embodiments, the tandem solar cell further comprises a contact layer under the first and second solar-cell absorber layers.

In some embodiments, the tandem solar cell further comprises a dichroic mirror between the first and second solar cells for dividing the solar radiation spectrum between the first and second solar cells.

In some embodiments of the tandem solar cell, the first solar cell further includes a glass layer, a transparent electrode layer, and a contact layer.

In some embodiments of the tandem solar cell, the glass and transparent electrode layers are over the first solar-cell absorber and contact layers, the contact layer is under the first solar-cell absorber layer, and the transparent electrode layer is under the glass layer.

In some embodiment of the tandem solar cell, the other one of the first and second solar cells further includes an emitter layer or a transparent electrode layer, and a contact layer.

In some embodiments of the tandem solar cell, the emitter layer or the transparent electrode layer is over the second solar-cell absorber and contact layers, and the contact layer is under the second solar-cell absorber layer.

In some embodiments of the tandem solar cell, the metal-halide double perovskite material has the formula A₂BB′X₆, where A is an inorganic cation, an organic cation, or a mixture of organic and inorganic cations, where B and B′ are metals, and where X is a halide or a mixture of halides.

In some embodiments of the tandem solar cell, A is Cs, Rb, K, Ba, CH₃NH₃, or (NH₂)₂CH, where B is Bi, Ag, Sn, In, Sb, Cu, Na, K, or Au of a predetermined oxidation state, where B′ is Bi, Ag, Sn, In, Sb, Cu, Na, K, or Au of various oxidation states, and where X is Br, I, Cl, or F.

In some embodiments of the tandem solar cell, the metal-halide double perovskite material is Cs₂BiAgBr₆.

In some embodiments of the tandem solar cell, the second solar-cell absorber layer is made of Si or CIGS.

In some embodiments of the tandem solar cell, the one of the first and second solar cells including the first solar-cell absorber layer is a top solar cell and the other one of the first and second solar cells is a bottom solar cell.

A solar-cell absorber, according to the disclosure, comprises a metal-halide double perovskite material.

In some embodiments of the solar-cell absorber, the metal-halide double perovskite material has the formula A₂BB′X₆, where A is an inorganic cation, an organic cation, or a mixture organic and inorganic cations, where B and B′ are metals, and where X is a halide or a mixture of halides.

In some embodiments of the solar-cell absorber, A is Cs, Rb, K, Ba, CH₃NH₃, or (NH₂)₂CH, where B is Bi, Ag, Sn, In, Sb, Cu, Na, K, or Au of a predetermined oxidation state, where B′ is Bi, Ag, Sn, In, Sb, Cu, Na, K, or Au of various oxidation states, and where X is Br, I, Cl, or F.

In some embodiments of the solar-cell absorber, the metal-halide double perovskite material is Cs₂BiAgBr₆.

A photovoltaic device, according the disclosure, comprises a metal-halide double perovskite material.

In some embodiments of the photovoltaic device, the metal-halide double perovskite material has the formula A₂BB′X₆, where A is an inorganic cation, an organic cation, or a mixture of organic and inorganic cations, where B and B′ are metals, and where X is a halide or a mixture of halides.

In some embodiment of the photovoltaic device, A is Cs, Rb, K, Ba, CH₃NH₃, or (NH₂)₂CH, where B is Bi, Ag, Sn, In, Sb, Cu, Na, K, or Au of a predetermined oxidation state, where B′ is Bi, Ag, Sn, In, Sb, Cu, Na, K, or Au of various oxidation states, and where X is Br, I, Cl, or F.

In some embodiments of the photovoltaic device, the metal-halide double perovskite material is Cs₂BiAgBr₆.

A composition for use in making photovoltaic device, according to the disclosure, comprises a metal-halide double perovskite material.

In some embodiments of the composition, the metal-halide double perovskite material has the formula A₂BB′X₆, where A is an inorganic cation, an organic cation, or a mixture of organic and inorganic cations, where B and B′ are metals, and where X is a halide or a mixture of halides.

In some embodiments of the composition, A is Cs, Rb, K, Ba, CH₃NH₃, or (NH₂)₂CH, where B is Bi, Ag, Sn, In, Sb, Cu, Na, K, or Au of a predetermined oxidation state, where B′ is Bi, Ag, Sn, In, Sb, Cu, Na, K, or Au of various oxidation states, and where X is Br, I, Cl, or F.

In some embodiments of the composition, the metal-halide double perovskite material is Cs₂BiAgBr₆.

### BRIEF DESCRIPTION OF THE DRAWINGS

FIG. 1A depicts the X-ray crystal structure of an ordered double perovskite Cs₂AgBiBr₆ of the disclosure. The Bi, Ag, Cs, and Br atoms are represented by reference numerals 10, 11, 12, and 13, respectively.

FIG. 1B is a photograph of a single crystal of Cs₂AgBiBr₆.

FIG. 1C depicts the Bi′ face-centered-cubic sublattice in Cs₂AgBiBr₆.

FIGS. 2A-2C graphically show the optical characterization of Cs₂AgBiBr₆.

FIG. 2A is a graph showing the wavelength-dependent absorbance of a powder sample of Cs₂AgBiBr₆. Inset in the graph is a Tauc plot showing the characteristics of an indirect band gap. FIG. 2B is a graph showing the steady-state room-temperature photoluminescence (PL) spectrum of a powdered sample of Cs₂AgBiBr₆ upon 500-nm excitation. Inset in the graph is a low-temperature PL spectrum. FIG. 2C is a graph showing the time-resolved room-temperature PL and fits for the PL decay time (τ) in powder and single-crystal samples of Cs₂AgBiBr₆.

FIG. 3A is a graph showing calculated (reference numeral 14) and experimental (reference numeral 15) powder X-ray diffraction patterns (PXRD) of Cs₂AgBiBr₆. PXRD patterns of Cs₂AgBiBr₆ obtained after a 30-day exposure to a relative humidity of 55% (reference numeral 16) and after a 30-day exposure to light (0.75 Sun) at 50° C. (reference numeral 18). Asterisks denote signals from the sample holder.

FIG. 3B is a graph showing PXRD data for Cs₂AgBiBr₆ after heating at 100° C. for 72 hours showing no decomposition, and PXRD data for (CH₃NH₃)PbX₃ (X=Br and I) after heating at 60° C. for 72 hours showing decomposition to PbX₂. Vertical bars denote reflections from PbX₂.

FIG. 3C is a graph showing the valence band maximum and conduction band minimum for Cs₂AgBiBr₆ compared to the energy levels for other materials relevant to photovoltaic devices with perovskite absorbers.

FIG. 4 is a graph showing the results of thermogravimetric analysis of Cs₂AgBiBr₆.

FIG. 5A is a graph showing a Tauc plot of the absorbance data for a direct allowed transition in Cs₂AgBiBr₆. Fits to the linear portion of the plot give the direct bandgap as 2.21 eV.

FIG. 5B is a graph showing a work function determination using photoelectron spectroscopy in air (PESA) on a pressed pellet of Cs₂AgBiBr₆.

FIG. 5C is a graph showing full fit of the single-crystal time-resolved photoluminescence data.

FIG. 5D is a graph showing full fit of the powder time-resolved photoluminescence data.

FIG. 5E is a graph showing thermogravimetric analyses of Cs₂AgBiBr₆ and (MA)PbBr₃ at a scan rate of 5° C./min and 1° C./min, respectively. Solid (MA)PbBr₃ shows an initial mass loss at 176° C. Solid Cs₂AgBiBr₆ shows an initial mass loss at 430° C. Differential thermal analysis (DTA) of Cs₂AgBiBr₆ shows no phase changes until the mass loss onset.

FIG. 5F is an electron micrograph of Cs₂AgBiBr₆ powder used for TRPL measurements. The sample has a large distribution of particle sizes but the majority are between 1-20 μm.

FIG. 5G is a graph showing powder XRD of the sample stage. Peaks shown here correspond to reflections marked by asterisks in FIG. 3A.

FIG. 5H is an X-ray photoelectron spectroscopy of a single crystal of Cs₂AgBiBr₆. Signals from O, C, and Si originate from the adhesive tape used to hold the sample.

FIG. 6 is a schematic representation of a solar cell device according to an embodiment of the present disclosure.

FIG. 7 is a schematic representation of a mechanically stacked tandem solar cell device according to an embodiment of the present disclosure.

FIG. 8 is a schematic representation of a dichroic mirror tandem solar cell device according to an embodiment of the present disclosure.

FIG. 9 is a schematic representation of a monolithically integrated tandem solar cell device according to an embodiment of the present disclosure.

FIG. 10 is a Table which lists crystallographic data for Cs₂AgBiBr₆.

### DETAILED DESCRIPTION

Disclosed herein are the synthesis, structure and optoelectronic properties of the 3D double perovskite Cs₂Ag^{I}Bi^{III}Br₆ of the present disclosure. This material has an indirect bandgap of 1.95 eV, which in various embodiments, is suited for coupling with a silicon (Si) solar-cell absorber in a tandem solar cell. Cs₂AgBiBr₆ also has a notably long room-temperature photoluminescence lifetime of ca. 660 ns. This value is much higher than the recombination lifetime for high-quality (MA)PbBr₃ films (170 ns) and approaches the unusually long lifetimes observed for (MA)PbI₃ films (736 ns-1 μs). Importantly, PL decay curves of Cs₂AgBiBr₆ show that the majority of carriers recombine through this long-lived radiative process, with only a 6% loss moving from single crystals and powders. This suggests that defects/surface sites will not be detrimental to the material's photovoltaic performance. Furthermore, Cs₂AgBiBr₆ is substantially more heat and moisture stable compared to (MA)PbI₃. Accordingly, one of ordinary skill in the art will appreciate that Cs₂AgBiBr₆ of the present disclosure is particularly useful as a solar radiation absorber for lead-free perovskite solar cells, although it is not limited to such applications.

The bandgap transition of lead-halide perovskites corresponds to a ligand-to-metal charge transfer from the predominantly halide p-orbital based valence-band-maximum (VBM) to the conduction-band-minimum (CBM), which has mostly lead p-orbital character. The 6s²6p⁰ electronic configuration of the Pb²⁺ allows for the filled 6s orbital to mix with the iodide 5p orbitals in the valence band, while the vacant lead 6p orbitals form the conduction band. Calculations have identified this VBM and CBM composition as contributing to the material's shallow defect states and long carrier lifetimes, while the high p-orbital based density of states near the band edges provide for the material's strong absorption. Only three main group elements have stable cations with the 6s²6p⁰ electronic configuration: Tl⁺, Pb²⁺, and Bi³⁺. Out of these candidates only bismuth has low toxicity and has been used for decades as a nontoxic replacement for lead in areas ranging from organic synthesis to materials for ammunition. Therefore, in accordance with some embodiments of the present disclosure, Bi³⁺ is incorporated as a B-site cation in the ABX₃ (where X=halide) perovskite framework. In order to accommodate the trivalent Bi³⁺ ion in the perovskite lattice, various embodiments of the present disclosure incorporate a monovalent transition metal, alkali metal, or main group cation in the perovskite framework, which yields a double-perovskite structure A^{I}₂B^{I}Bi^{III}X₆ (where X=halide).

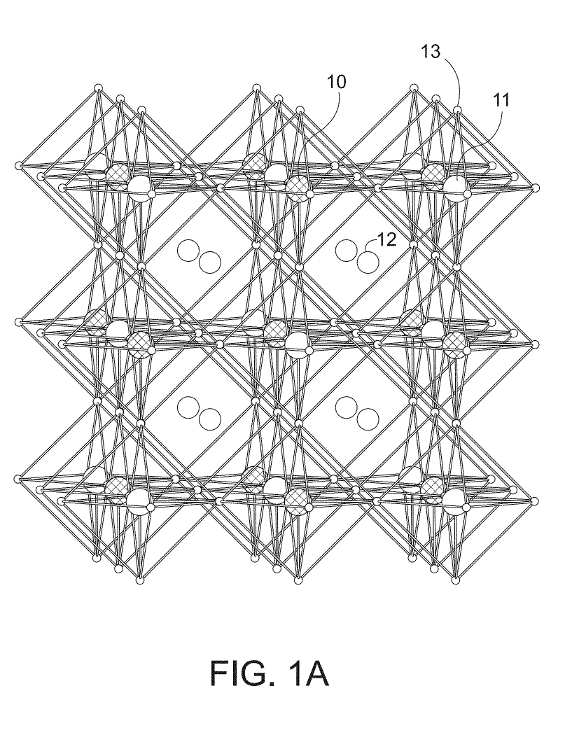

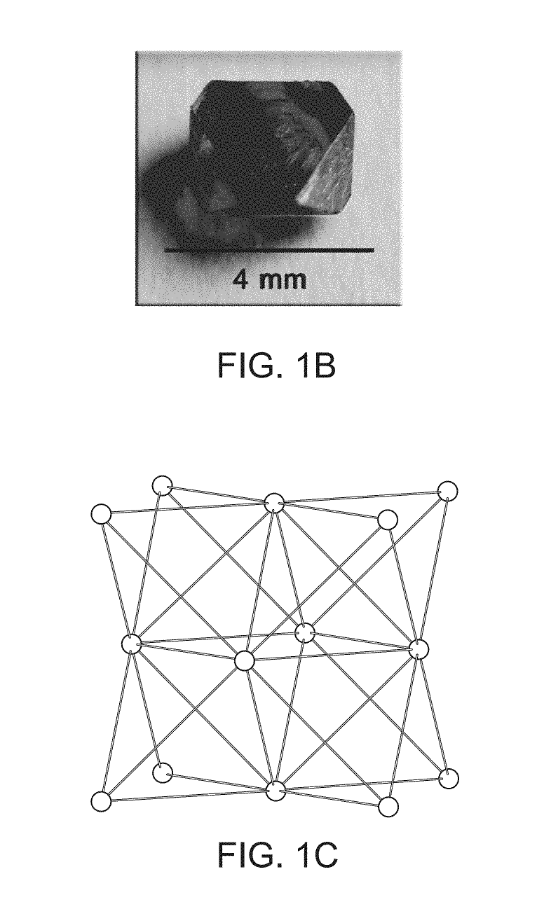

The oxide double perovskites A₂BB′O₆ have been well explored and are known to incorporate a wide variety of metals in various oxidation states. In ordered double perovskites, the B and B′ sites alternate in the lattice as shown in FIG. 1A. Such perovskites with paramagnetic ions residing only in the B (or B′) sublattice, as shown in FIG. 1C, have been used for studying exotic magnetic ground states arising from spin frustration. Unusual electronic states, such as metallic ferromagnetism and colossal magnetoresistance, have also been realized in oxide double-perovskite lattices. There are, however, only a handful of reports of halide double perovskites. These include the mixed-valence compounds A₂Au^{I}Au^{III}X₆ (where A=K, Rb, or Cs; and where X=Cl, Br, or I), which have been explored as potential superconductors, and the cubic perovskites Cs₂Tl^{I}Tl^{III}X₆ (where X=F or Cl) and Cs₂AgAuCl₆. The x=0.5 member of the solid solution (MA)SnₓPb₁₋ₓI₃ could also be considered a disordered double perovskite, although the term has not been typically used.

In keeping with the radius-ratio rules that describe packing in ionic solids, Ag⁺ is of an appropriate size to support octahedral coordination of iodides or bromides in the perovskite lattice. Therefore, in accordance with the present disclosure, Ag⁺ ions are used to incorporate bismuth cations into a 3D halide double-perovskite, to synthesize the novel Cs₂AgBiBr₆ of the present disclosure. In 2D halide perovskites, Bi³⁺ is incorporated into the inorganic sheets by introducing lattice vacancies. Large single crystals of Cs₂AgBiBr₆ can be crystallized from a concentrated HBr solution containing stoichiometric CsBr, AgBr, and BiBr₃. The perovskite crystallizes as red-orange truncated octahedra in the cubic space group Fm-₃m, as shown in FIG. 1B. The unit-cell axis of 11.25 Å is roughly double that of (MA)PbBr₃ (a=5.92 Å). The Ag⁺ and Bi³⁺ ions occupy the B and B′ sites in the ordered double-perovskite lattice with slightly different metal-bromide bond lengths. No crystallographic evidence is seen for disorder between the Bi and Ag sites.

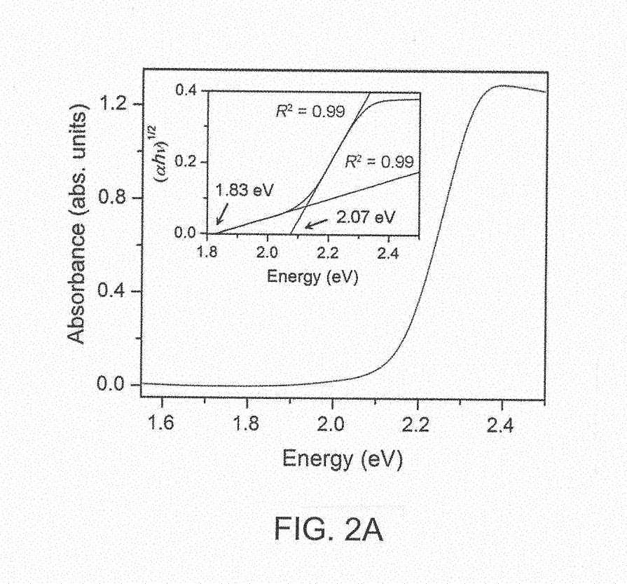

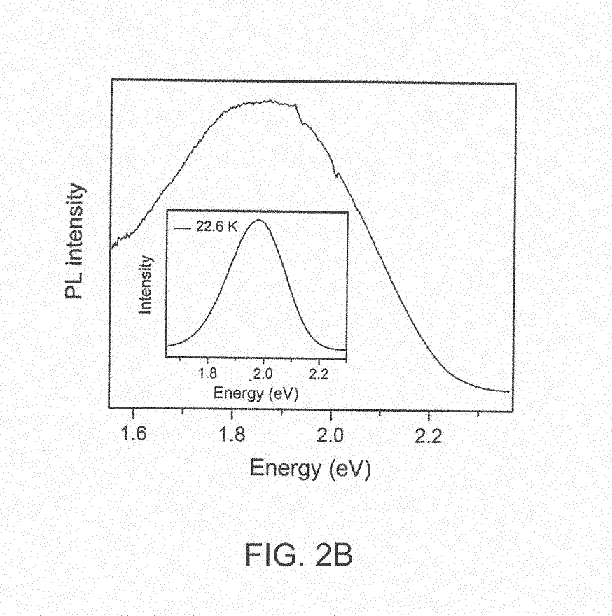

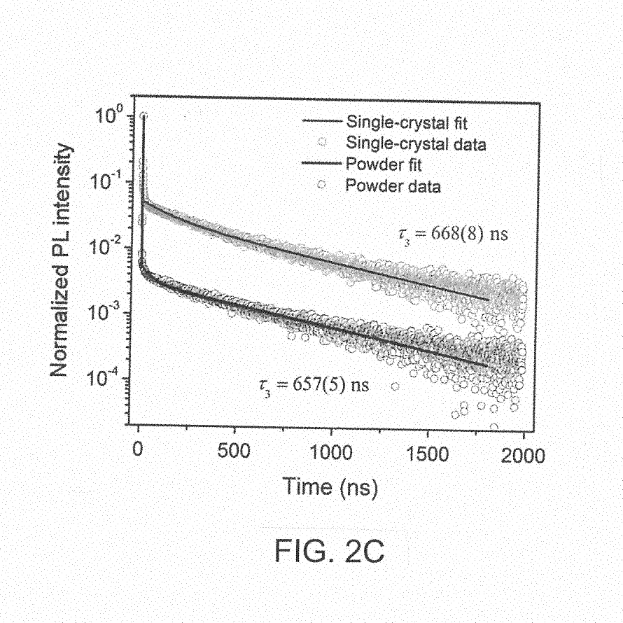

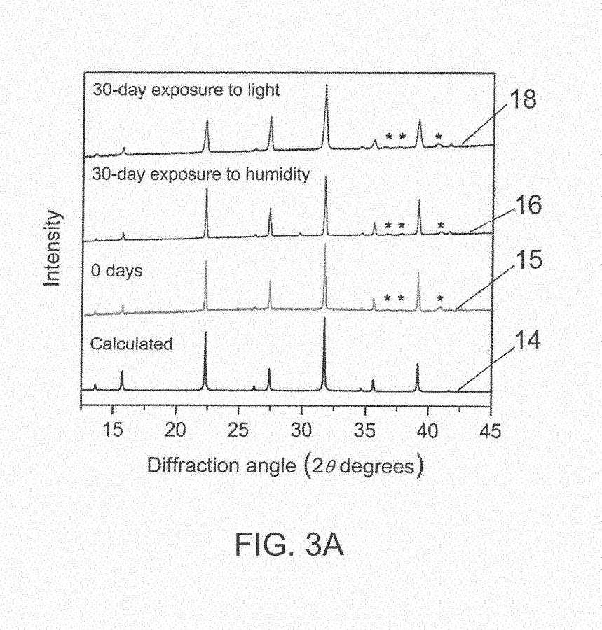

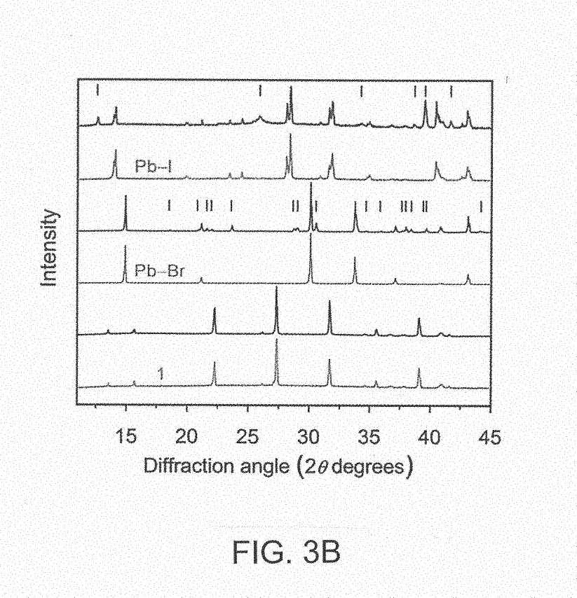

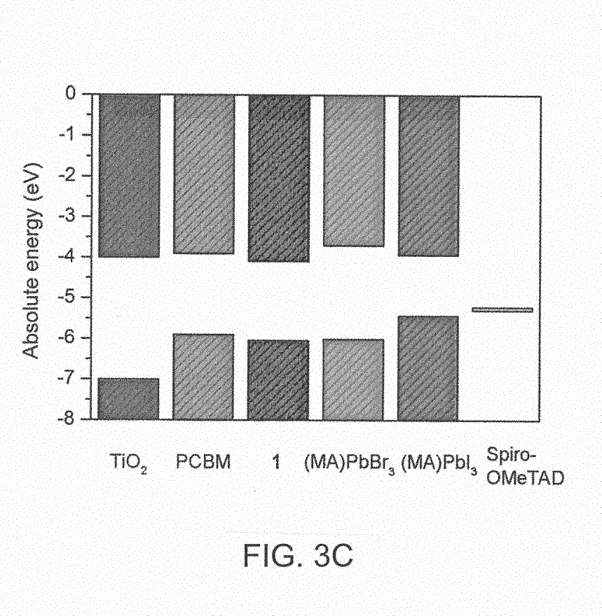

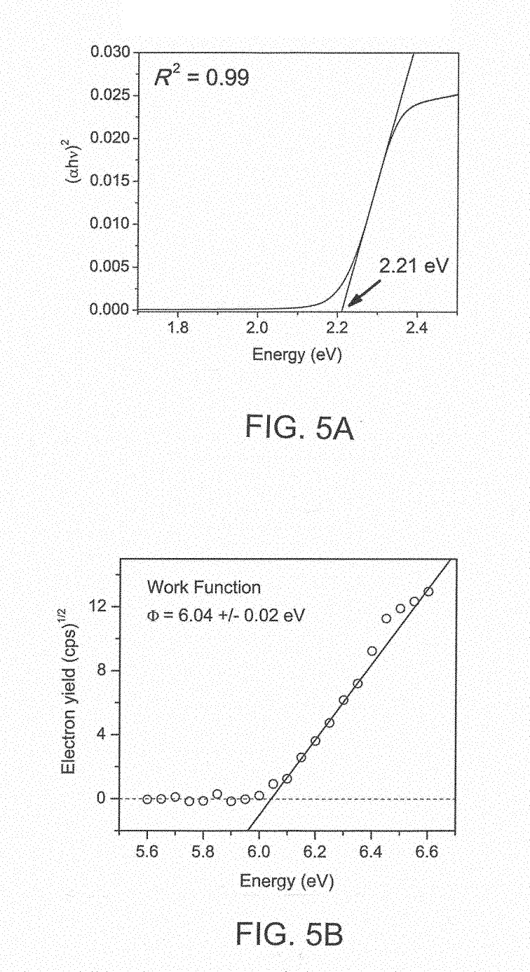

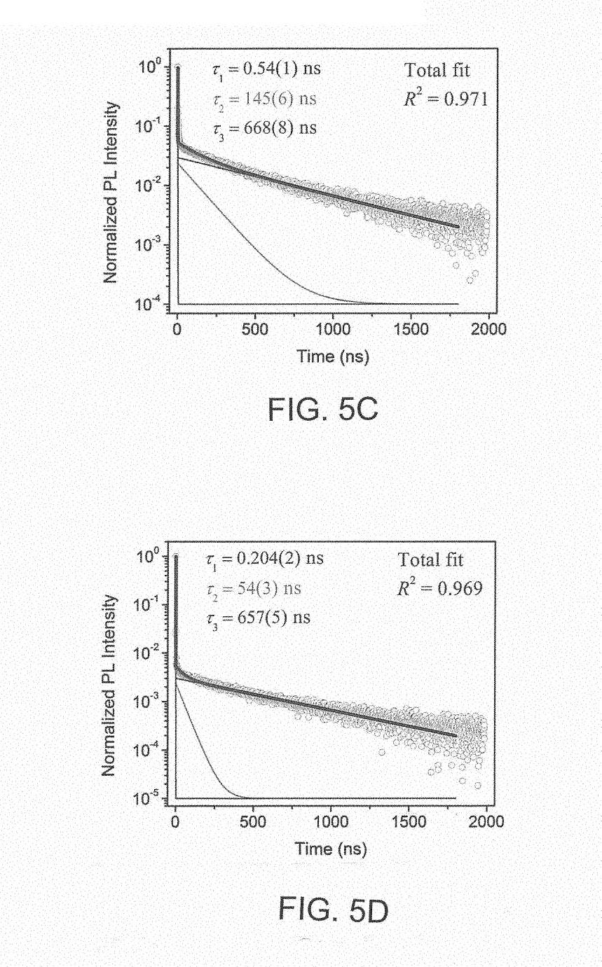

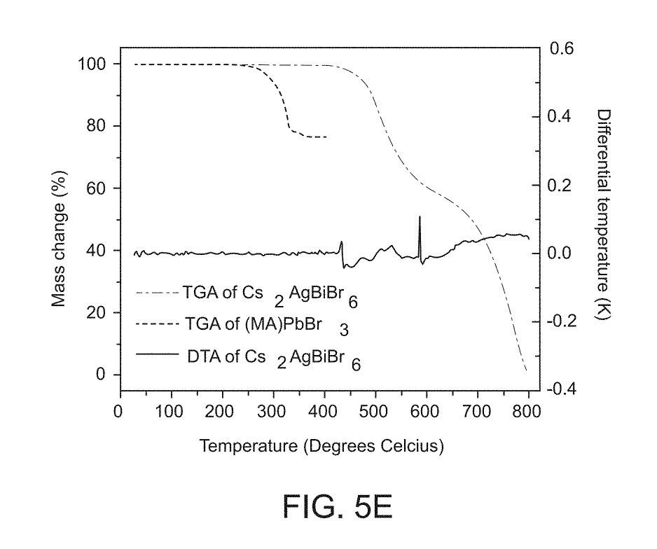

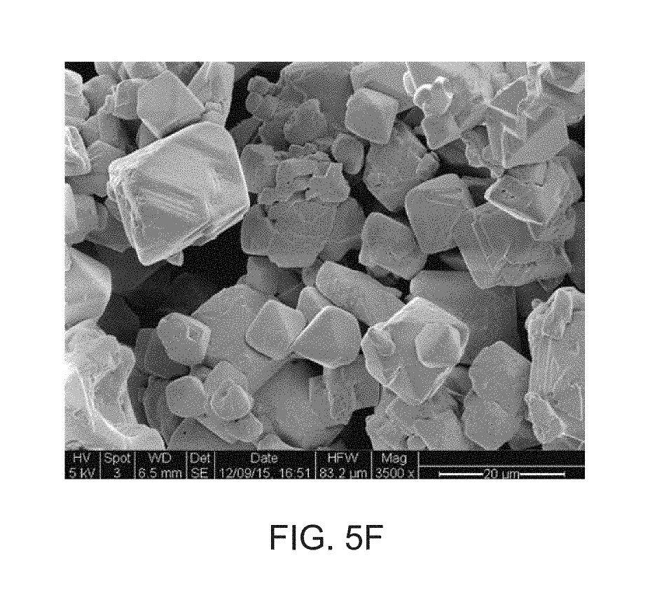

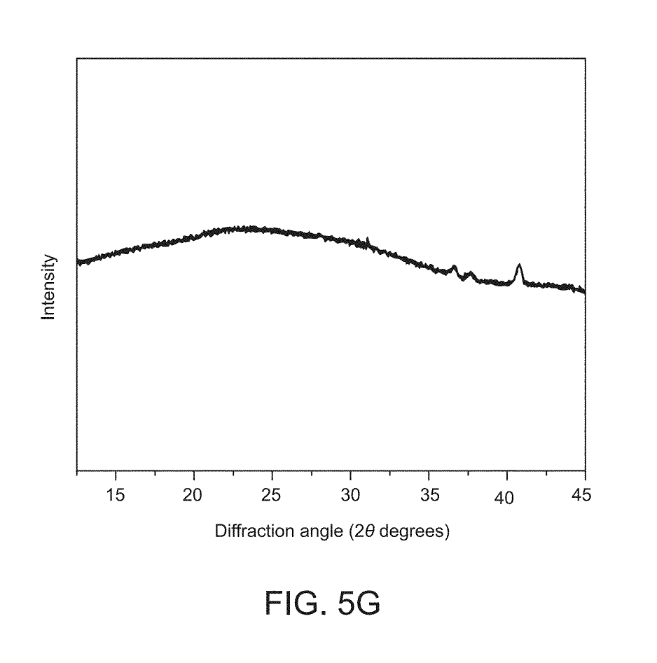

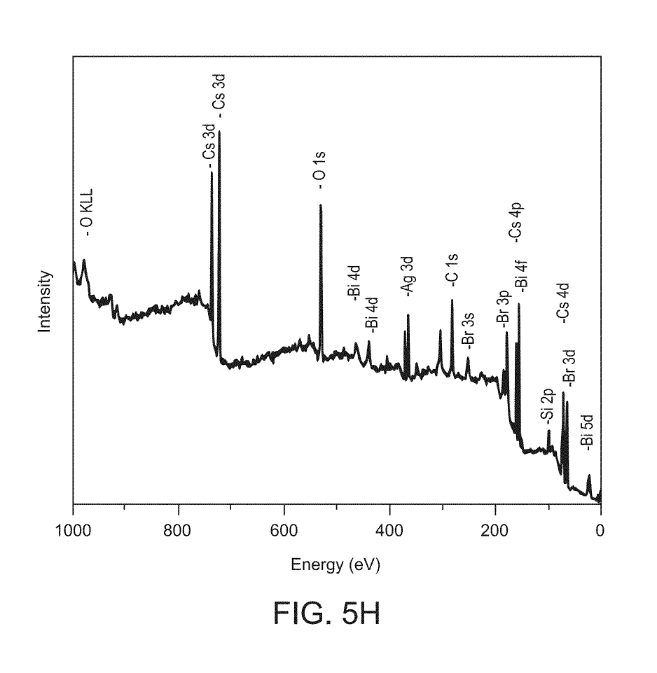

The Cs₂AgBiBr₆ of the present disclosure has an optical bandgap that makes its suitable for photovoltaic applications. The perovskite shows the characteristics of an indirect bandgap semiconductor with a shallow absorption region beginning at 1.8 eV followed by a sharp increase in absorption near 2.1 eV, as shown in FIG. 2A. A Tauc plot of the data, assuming an indirect allowed transition, is shown in the inset of FIG. 2A. The linear regions of the plot show the expected phonon-assisted processes, with transitions at 1.83 eV and 2.07 eV occurring with absorption and emission of a phonon, respectively. This allows the indirect bandgap to be estimated as 1.95 eV with an assisting phonon energy of 0.12 eV. A Tauc plot, assuming a direct allowed transition, gives a direct bandgap of 2.21 eV, as shown in FIG. 5A, slightly lower than the bandgap of 2.3 eV reported for (MA)PbBr₃. At room temperature, Cs₂AgBiBr₆ displays photoluminescence (PL) centered at 1.87 eV, as shown in FIG. 2B. The low-temperature PL is more intense and blueshifted with the peak centered at 1.98 eV at 23 K, as shown in the inset of FIG. 2B. Therefore, in accordance with one embodiment of the present disclosure, the Cs₂AgBiBr₆ comprises a top or higher-bandgap solar-cell absorber in a tandem solar cell. The band gap of 1.95 eV in Cs₂AgBiBr₆ is near optimal for pairing with a bottom or lower-bandgap silicon solar-cell absorber (bandgap of 1.1 eV), as four- and two terminal tandem solar cells with silicon absorbers require higher-bandgap absorbers with ideal bandgaps of 1.8 eV and 1.8-1.9 eV, respectively. Photoelectron spectroscopy in air (PESA) gives the VBM for Cs₂AgBiBr₆ as −6.04 eV with respect to vacuum, as shown in FIG. 5B, similar to that of (MA)PbBr₃ (−6.01 eV). FIG. 3C shows a band diagram comparing the CBM and VBM of Cs₂AgBiBr₆ of materials relevant to perovskite solar cells.

The fate of photogenerated carriers in Cs₂AgBiBr₆ was determined by obtaining room-temperature time-resolved PL data, as shown in FIG. 2C. The PL intensity shows a fast initial drop followed by a slower decay. Analysis of the entire time trace required three processes: a short-lifetime process (τ₁<1 ns), an intermediate-lifetime process (τ₂=50-150 ns) and a long-lived component (τ₃=ca. 660 ns). Time constants for the short and intermediate PL decay processes for single-crystal and powder samples are given in FIGS. 5C and 5D, respectively. While analysis of the short-lived process's lifetime was limited by instrumental resolution, the magnitude of this process (PL intensity×time) is larger in the powder than in the single crystal. Additionally, the lifetime of the intermediate process was much shorter in the powder (54 ns) compared to the single crystal (145 ns). Because powders typically have many more defects and surface states than a single crystal, this suggests that the short- and intermediate-lifetime processes may originate from trap and/or surface-state emission. The large PL decay constant of ca. 660 ns does not vary significantly between the single-crystal and powder samples and likely gives the material's fundamental radiative lifetime. These values are significantly higher than those reported for high-quality (MA)PbBr₃ films (170 ns) and approach those reported for (MA)PbI₃ films, which have been optimized from 736 ns up to ca. 1 μs. Although indirect bandgap semiconductors have longer PL lifetimes compared to direct bandgap materials, the long radiative lifetime in Cs₂AgBiBr₆ is unusual, especially for powders. Integrating the PL traces, it is estimated that 85% of excited carriers emit via the long-lived radiative process in the crystal compared to 80% for the powder, as discussed below in the Experimental Section. The ratio of these values indicates that faster PL decay components increase by only 6% in powders compared to crystals, attesting to the material's robustness to defects.

As (MA)PbI₃ has been shown to be unstable to moisture and noting that silver halides are notoriously light sensitive, the stability of Cs₂AgBiBr₆ to both light and moisture was investigated. Freshly prepared powder samples of Cs₂AgBiBr₆ were stored either in the dark at 55% relative humidity or irradiated at 50° C. with a broad spectrum halogen lamp (0.75 Sun) under dry N₂ for 30 days. As shown in FIG. 3A, powder X-ray diffraction (PXRD) patterns of Cs₂AgBiBr₆ after moisture (reference numeral 16) or light exposure (reference numeral 18) showed no evidence of material decomposition. After 15 days some of the irradiated samples showed small localized surface discolorations. These spots recovered their original color upon storing the sample in ambient light for two days.

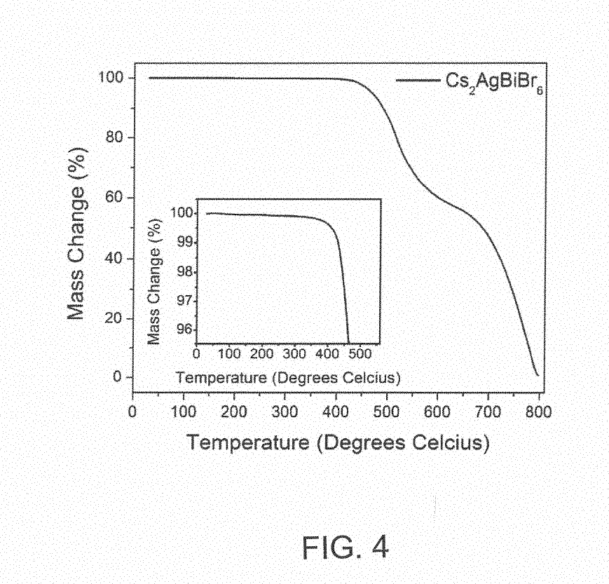

Thermal stability is also important for solar-cell absorbers, which can reach temperatures of ca. 60-85° C. during typical device operating conditions and still higher temperatures during device fabrication. As shown in FIG. 4, thermogravimetric analysis (TGA) shows that Cs₂AgBiBr₆ is stable to mass loss up to 340° C. and differential thermal analysis indicates no phase transitions within this temperature range, as shown in FIG. 5E. PXRD patterns obtained after heating Cs₂AgBiBr₆ at 100° C. in air for 72 hours confirms structural integrity, as shown in FIG. 3B. The absence of volatile organic components likely increases Cs₂AgBiBr₆'s thermal stability with respect to (MA)PbX₃ (where X=I and Br). Although TGA data collected at fast heating rates suggest material stability, (MA)PbX₃ slowly loses CH₃NH₃ and HX even at moderate temperatures. PXRD data of (MA)PbX₃ heated at 60° C. for 72 hours in air show decomposition to PbX₂, as shown in FIG. 3B. Although encapsulation may impede this decomposition pathway, inherent thermal stability is an advantage for material processing and its long-term usage.

Results indicate that Cs₂AgBiBr₆ preserves many of the desirable properties of (MA)PbI₃ and (MA)PbBr₃ for solar-cell applications while removing the toxic element, lead. Although silver can be toxic, the solubility constant for AgBr (Kₛₚ at 25° C.=5×10⁻¹³) is ca. 10⁴ times lower than for PbI₂, which greatly reduces contamination risks. Substitution of different B-site cations for Ag⁺ in the double-perovskite could further reduce the material's toxicity.

Despite the massive interest in halide perovskite photovoltaics, the A^{I}B^{II}X₃ (where X=halide) perovskite lattice has proven restrictive for incorporating stable and nontoxic metals. The double perovskite structure A₂BB′X₆ of the present disclosure provides a more accommodating platform for varying the B-site substitutions. Here, many combinations of metals in different oxidation states can be incorporated into the BB′ sublattices, while both organic (CH₃NH₃⁺, (NH₂)₂CH⁺) and inorganic (Cs⁺, Rb⁺) cations can be incorporated into the A sites. In further embodiments of A₂BB′X₆, other 1+ cations can be used for the B site in place of Ag⁺, such as but not limited to In⁺. In still further embodiments of A₂BB′X₆, other 3+ cations can be used for the B′ site in place of Bi³⁺, such as but not limited to Sb³⁺. In still further embodiments of A₂BB′X₆, other 1+ cations can be used for the A site in place of Cs⁺, such as but not limited to methylammonium, Rb⁺, and formamidinium. In still further embodiments of A₂BB′X₆, other 1− anions can be used for the X in place of Br¹⁻, such as I¹⁻, or a mixture of I¹⁻ and Br¹⁻. Various other embodiments of A₂BB′X₆ can comprise any combination of the previous embodiments. In still further embodiments, double perovskites can also be formed with other combinations of oxidation states for the A- and B-site metals.

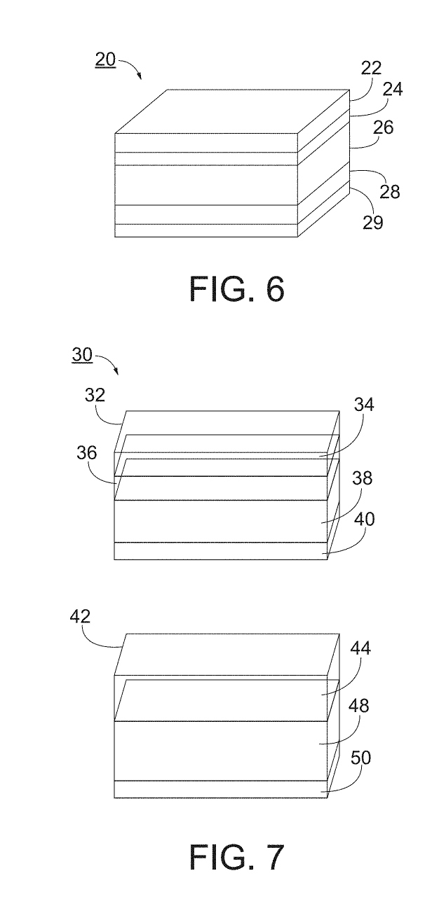

FIG. 6 schematically represents a solar cell device 20 according to an embodiment of the disclosure. The solar cell 20 includes a first electrode layer 22, a hole-selective contact layer 24, a perovskite solar-cell absorber layer 26 which comprises the halide double perovskite material of the present disclosure, an electron-selective contact layer 28, and a second electrode layer 29. The first electrode layer 22 can comprise gold or any other suitable electrode material. The hole-selective contact layer 24 can comprise spiro-OMeTAD (2,2′,7,7′-Tetrakis(N,N-di-p-methoxyphenylamine)-9,9′-spirobifluorene) or any other suitable hole-selective contact material. The electron-selective contact layer 28 can comprise TiO₂ or any other suitable electron-selective contact material. The second electrode layer 29 can comprise fluorine doped tin oxide (FTO), indium doped tin oxide (ITO) or any other suitable transparent electrode material.

FIG. 7 schematically represents a mechanically stacked tandem solar cell device 30 according to an embodiment of the disclosure. The mechanically stacked tandem solar cell device 30 includes a separate top solar cell 32 of a first type, which receives incident light energy impinging on the device 30 and a separate bottom solar cell 42 of a second type. The top solar cell 32 includes glass layer 34, a first transparent electrode layer 36 (made of FTO, ITO, or any other suitable transparent electrode material), a (top) solar-cell absorber layer 38, which comprises the halide double perovskite material of the present disclosure, and a second transparent electrode layer 40 (made of FTO, ITO, or any other suitable transparent electrode material). The bottom solar cell 42 includes a Si or CIGS (bottom) solar-cell absorber layer 48, an emitter or transparent electrode layer 44, and a rear contact layer 50 (made of Au, Ag or any other suitable contact material). Layer 44 comprises an emitter layer if the solar-cell absorber layer 48 comprises Si. If the solar-cell absorber layer 48 comprises CIGS (copper indium gallium selenide), then layer 44 comprises a transparent electrode layer 44. The halide double perovskite solar-cell absorber layer 38 of the top solar cell 32 has a higher bandgap than the Si or CIGS bottom solar-cell absorber layer 48 of the bottom solar cell 42. Therefore, the two different solar cells 32, 42 increase the overall efficiency of the device 30 because the top solar cell 32 with the higher bandgap halide double perovskite solar-cell absorber layer 38 converts high energy photons into electricity and the bottom solar cell 42 with the lower bandgap Si or CIGS solar-cell absorber layer 48 converts the remaining low energy photons transmitted through the top solar 32 into electricity. Accordingly, a larger portion of the light energy is converted into electricity.

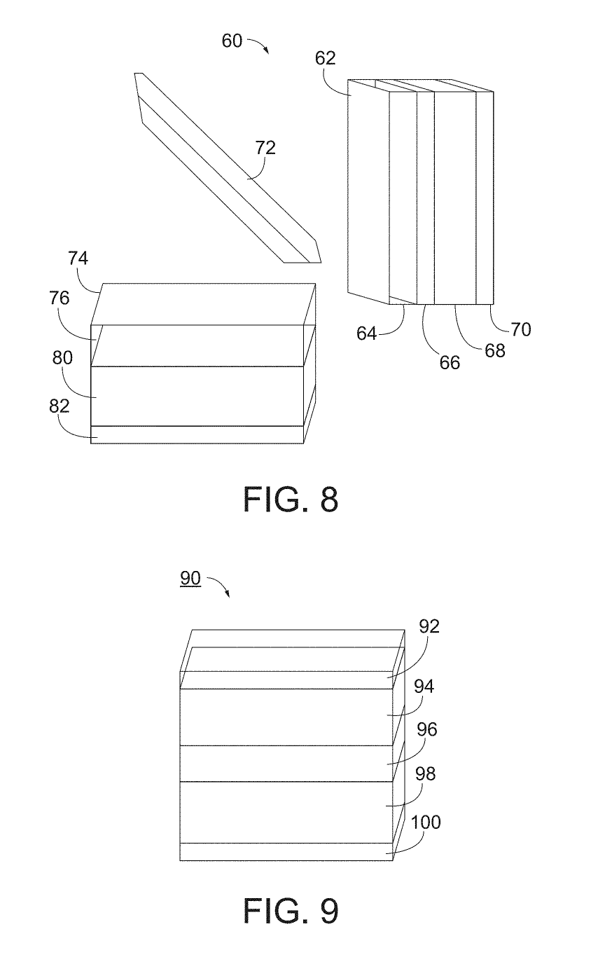

FIG. 8 schematically represents a dichroic mirror tandem solar cell device 60 according to an embodiment of the disclosure. The dichroic mirror tandem solar cell device 60 includes a separate top solar cell 62 of a first type, which receives incident light energy impinging on the device 30, a separate bottom solar cell 74 of a second type, and a dichroic mirror 72 between the top and bottom solar cells, 62 and 74, respectively, which divides the solar radiation spectrum between the solar cells 62, 74 so that a selected portion of the solar radiation spectrum is reflected toward the bottom solar cell 74 and the remaining portion of the solar radiation spectrum passes through the mirror 72 to the top solar cell 62. The top solar cell 62 includes a glass layer 64, a transparent electrode layer 66 (made of FTO, ITO, or any other suitable transparent electrode material), a (top) solar-cell absorber layer 68, which comprises the halide double perovskite material of the present disclosure, and a rear contact layer 70 (made of Au, Ag or any other suitable contact material). The bottom solar cell 74 includes a Si or CIGS (bottom) solar-cell absorber layer 80, an emitter or transparent electrode layer 76, and a rear contact layer 82 (made of Au, Ag or any other suitable contact material). Layer 76 comprises an emitter layer if the solar-cell absorber layer 80 comprises Si. If the solar-cell absorber layer 80 comprises CIGS (copper indium gallium selenide), then layer 76 comprises a transparent electrode layer 44. As in the embodiment of FIG. 7, the two different solar cells 62, 74 increase the overall efficiency of the device 60 because the top solar cell 62 with the higher bandgap halide double perovskite solar-cell absorber layer 68 converts the high energy photons into electricity and the bottom solar cell 74 with the lower bandgap Si or CIGS solar-cell absorber layer 80, converts the remaining low energy photons transmitted through the top solar 62 into electricity.

FIG. 9 schematically represents a monolithically integrated tandem solar device 90 according to an embodiment of the disclosure. The monolithically integrated tandem solar cell device 90 includes a top solar-cell absorber layer 94 of a first type, which receives incident light energy impinging on the device 30, and a bottom solar-cell absorber layer 98 of a second type connected in series. A transparent electrode layer 92 (made of FTO, ITO, or any other suitable transparent electrode material) is disposed over the top solar-cell absorber layer 94 and a rear contact layer 100 (made of Au, Ag, or any other suitable contact material) is disposed over the bottom solar-cell absorber layer 98. The top solar-cell absorber layer 94 comprises the halide double perovskite material of the present disclosure and the bottom solar-cell absorber layer 98 comprises Si or CIGS. A tunnel junction/recombination layer 96 series connects the top solar-cell absorber layer 94 with the bottom solar-cell absorber layer 98. Similar to the devices of FIGS. 7 and 8, the two different solar-cell absorber layers 94, 98 increase the overall efficiency of the device 90 because the top solar-cell absorber layer 94 with the higher bandgap converts the high energy photons into electricity and the bottom Si or CIGS solar-cell absorber layer 98 with the lower bandgap, converts the remaining low energy photons transmitted through the top solar-cell absorber layer 94 into electricity.

It should be understood that the tandem solar devices of the present disclosure can include more than two solar cells. In such embodiments, one or more of the solar cells can include a solar-cell absorber layer or solar-cell absorber comprising the halide double perovskite material of the present disclosure.

The halide double perovskite material forming the solar-cell absorber of the solar cell devices of FIGS. 6-9, can have a structure comprising A₂BB′X₆ (where X is a halide). In some embodiments, the A₂BB′X₆ can be Cs₂BiAgBr₆. In various other embodiments, each of the elements of Cs₂BiAgBr₆ can be varied. In some embodiments, the Bi/Ag can be replaced with other metals including without limitation Sn, In, Sb, Cu, Na, K, and Au, and their oxidation states can be varied including without limitation 1+, 2+, 3+, and 4+. In some embodiments, the Cs can be replaced with inorganic and organic cations including without limitation Rb⁺, K⁺, Ba²⁺, CH₃NH₃⁺, and (NH₂)₂CH⁺. In some embodiments, Br can be replaced with, but not limited to I, Cl, and F or a mixture of halides.

The solar cells of the present disclosure can be fabricated using well known semiconductor and microelectronic fabrication methods including sequential solution- or vapor-deposition and evaporation.

Experimental Section

All manipulations were conducted in air unless otherwise noted. Solvents were of reagent grade or higher purity. All reagents were purchased from commercial vendors and used as received.

Synthesis of Cs₂AgBiBr₆

Solid CsBr (0.426 g, 2.00 mmol) and BiBr₃ (0.449 g, 1.00 mmol) were dissolved in 10 mL of 9-M HBr. Solid AgBr (0.188 g, 1.00 mmol) was then added to the solution and the vial was capped and heated to 110° C. The solution was held at 110° C. for 2 h and then cooled to room temperature. An orange powder precipitated from solution upon sitting at room temperature for ca. 2 h. This solid was filtered on a glass frit and dried under reduced pressure overnight to afford 0.623 g (58.7% yield) of product. Crystals suitable for structure determination were obtained by controlling the cooling rate at 2° C./hr. Larger crystals (such as the one shown in FIG. 1B) were obtained by cooling to room temperature at 1° C./hr.

Crystal Structure Determination

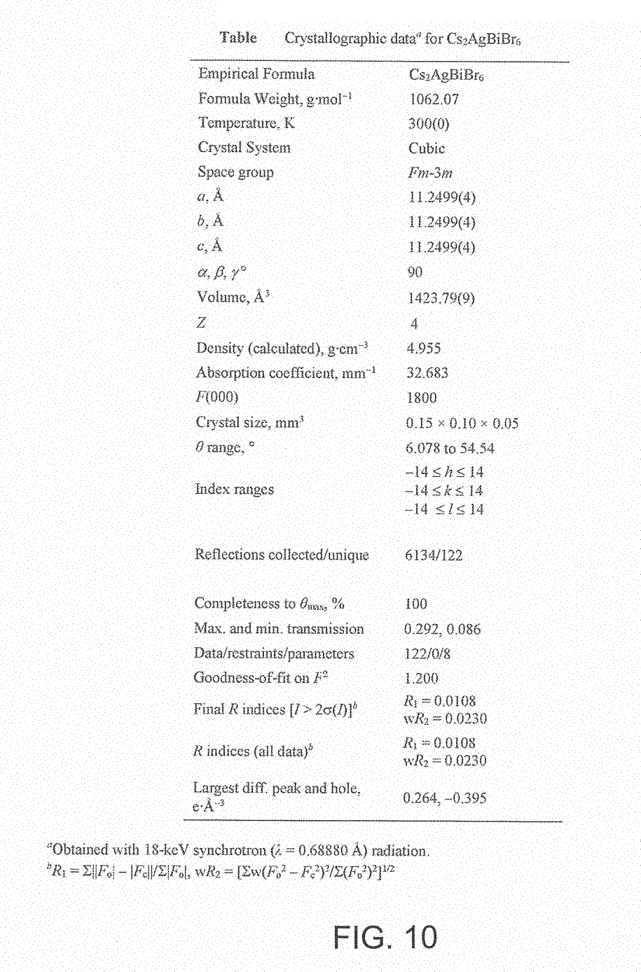

A crystal of Cs₂AgBiBr₆ was coated with Paratone-N oil, mounted on a Kapton® loop, and transferred to a Bruker D8 Venture diffractometer equipped with a Photon 100 CMOS detector. Frames were collected using ω and ψ scans with 18-keV synchrotron radiation (λ=0.68880 Å). Unit-cell parameters were refined against all data. The crystal did not show significant decay during data collection. Frames were integrated and corrected for Lorentz and polarization effects using SAINT 8.27b and were corrected for absorption effects using SADABS V2012.1 The space-group assignment was based upon systematic absences, E-statistics, agreement factors for equivalent reflections, and successful refinement of the structure. The structure was solved by direct methods, expanded through successive difference Fourier maps using SHELXS-97, and refined against all data using the SHELXTL-2013 software package. Weighted R factors, Rw, and all goodness-of-fit indicators are based on F2. Thermal parameters for all atoms were refined anisotropically. Crystallographic data for Cs₂AgBiBr₆ is listed in the Table shown in FIG. 10.

Optical Measurements

Absorption data were collected on a Cary 6000i UV-Vis spectrometer equipped with an integrating sphere operating in absorbance mode. A pressed powder sample was mounted on a quartz slide in the center of the sphere such that light was incident normal to the surface. Room-temperature steady-state emission spectra were collected on powders mounted on quartz slides using a Horiba Jobin-Yvon Spex Fluorolog-3 fluorimeter equipped with a 450-W xenon lamp and a thermoelectrically-cooled R928P detector. Incident light was passed through a double-grating monochromator and data were collected using the FluorEssence 2.3.15 software. Low-temperature photoluminescence (PL) was measured using a spectrograph (Acton Research SpectraPro 500i) equipped with a silicon CCD array detector (Hamamatsu). Samples were excited with a 488-nm InGaAs diode laser (Coherent, OBIS). Samples were cooled to liquid helium temperatures using a Janus ST-500 cold-finger cryostat.

Time-Correlated Single Photon Counting (TCSPC) Measurement

Measurement was performed using a TCSPC system (TimeHarp 260 PICO, PicoQuant). Powder and single-crystal samples were excited using a 500-fs fiber laser with the frequency doubled from the fundamental wavelength of 1030 nm to 515 nm. The repetition rate was decreased from 1.28 MHz to 426.7 kHz using an acousto-optic modulator (R35085-50-5-I-HGM-W, Gooch & Housego). PL was detected using a hybrid photomultiplier detector assembly (PMA Hybrid 06, PicoQuant). The detection wavelength was selected using 641/75 nm bandpass filters (Semrock, Inc.), and the excitation fluence was controlled using reflective neutral density filters (NDK01, Thorlabs, Inc.). The response function of the system has a full width at half maximum (Maki) of ca. 120 ps. Data were collected in 0.8-ns increments. Fluence was varied between 30 nJ/cm2 and 170 nJ/cm2 for these measurements.

TCSPC Fitting

TCSPC data were fit using OriginPro 8. Time points were shifted such that t=0 corresponded to the point of maximum intensity. The background signal was subtracted and the data were normalized on the interval [0,1]. The background was determined by taking the mean of the 13 data points immediately prior to t=0. The background varied between 1-4% and 0.1-0.7% of the maximum PL intensity for single-crystal and powder data sets, respectively. Fitting was only performed out to 1800 ns as later time points begin to merge with the detector noise. In order to prevent the large values at early time points from unduly influencing the fit a statistical weighting function, w(yi), was applied. The “best fit” was found by minimizing the weighted sum of least squares:

$${\sum }_{i}^{N} w ( {y}_{i} ) ⋆ {( {y}_{i} - {y}_{ifit} )}^{2} = {\sum }_{i}^{N} \frac{{( {y}_{i} - {y}_{ifit} )}^{2}}{{y}_{i}} Fits$$

were performed via an iterative process using the following general equation:

$$I ( t ) = {\sum }_{i} {I}_{i} {e}^{- t / {τ}_{i}}$$

The later part of the data (t>400 ns) was initially fit with a single exponential. Earlier time points were gradually included in the fit until the fit diverged from the data at which point a new exponential term was added. The addition of the new term was evaluated by comparing the χ² statistic of the fits with and without the new term. If χ² was reduced the new term was accepted and fitting continued. In all cases three exponential terms were found to best describe the data.

Calculation of the Magnitude of the Band-to-Band Radiative Transition

The integral out to infinite time of an exponential function has an analytical solution:

∫₀^{∞}Iᵢe^{(-t/τ}^{ᵢ}⁾dt=Iᵢ×τᵢ

Using the fit parameters for the long-lifetime PL decay process (E_{fit}=I₃τ₃) and numerical integration of the entire PL trace (Eₜₒₜ), we can estimate the fraction of excited carriers that relax via the long-lived band-to-band radiative transition in single-crystal and powder samples as (% Rad):

$$\begin{matrix}\frac{{E}_{fit , xtal}}{{E}_{tot , xtal}} ⋆ 100 = \% {Rad}_{xtal} = 85 \% \\ \frac{{E}_{fit , powder}}{{E}_{tot , poweder}} ⋆ 100 = \% {Rad}_{powder} = 80 \%\end{matrix}$$

The ratio of the single-crystal and powder percentages:

$$\frac{\% {Rad}_{powder}}{\% {Rad}_{xtal}} = .94$$

implies that the additional defects and surface sites present in the powder sample only reduce the band-to band recombination by 6% compared to the single crystal. Numerical integration of the entire PL trace (Eₜₒₜ) was performed in MATLAB using a trapezoidal integration algorithm (trapz).

Other Physical Measurements

Powder x-ray diffraction (PXRD) measurements were performed on a PANalytical X'Pert powder diffractometer with a Cu anode (Kα₁=1.54060 Å, K α₂=1.54443 Å, Kα₂/Kα₁=0.50000), a programmable divergence slit with a nickel filter, and a PIXcel^{1D} detector. The instrument was operated in a Bragg-Brentano geometry with a step size of 0.02° (2θ). The simulated PXRD pattern was calculated using the crystallographic information file (CIF) from the single-crystal X-ray diffraction experiment. Thermogravimetric and differential thermal analyses were performed with a Netzsch TG 209 F1 Libra Thermo-Microbalance with alumina pans at a heating rate of 5° C./min, using 30-mg samples. Photoelectron spectroscopy in air (PESA) measurements were performed using a Riken AC-2 photoelectron spectrometer on a pressed pellet of Cs₂AgBiBr₆. Scanning electron micrographs of powder samples were taken using a FEI XL30 Sirion SEM.

Stability Studies

Freshly prepared powder samples of Cs₂AgBiBr₆ were placed on clean glass slides for this experiment. For the humidity study a sample was placed on a platform inside a Teflon-capped glass jar. The bottom of the jar was filled with saturated Mg(NO₃)₂ solution so that the relative humidity above the surface of the liquid was maintained at 55%.5 The outside of the jar was covered with electrical tape to minimize light exposure. For the light stability study a sample was placed in a custom built chamber and irradiated with a broad spectrum halogen lamp (intensity=0.75 Suns, calibrated with a photodiode). The lamp irradiated the sample through the glass of the chamber so only wavelengths greater than 280 nm reached the sample. A thermocouple was placed within the chamber to monitor the sample temperature. The temperature varied from 45° C. to 65° C. over the course of the experiment with an average temperature of ca. 50° C. The sample was kept under flowing dry nitrogen gas. Both samples were checked by eye daily and monitored by PXRD at regular intervals. All samples were briefly exposed to ambient conditions during PXRD measurements.

Although the solar-cell absorber, solar-cell device, photovoltaic device and halide double perovskite material of the present disclosure have been described in terms of illustrative embodiments, they are not limited thereto. Rather, the appended claims should be construed broadly to include other variants and embodiments of same, which may be made by those skilled in the art without departing from the scope and range of equivalents thereof.

What is claimed is:

1. A solar cell comprising a solar-cell absorber layer made of a metal-halide double perovskite material.

2. The solar cell of claim 1, further comprising a hole-selective contact layer, an electron-selective contact layer, and first and second electrode layers.

3. The solar cell of claim 1, wherein the metal-halide double perovskite material has the formula A₂BB′X₆, where A is an inorganic cation, an organic cation, or a mixture of organic and inorganic cations, where B and B′ are metals, and where X is a halide or a mixture of halides.

4. The solar cell of claim 3, wherein A is Cs, Rb, K, Ba, CH₃NH₃, or (NH₂)₂CH, where B is Bi, Ag, Sn, In, Sb, Cu, Na, K, or Au of a predetermined oxidation state, where B′ is Bi, Ag, Sn, In, Sb, Cu, Ga, or Au of various oxidation states, and where X is Br, I, Cl, or F.

5. The solar cell of claim 1, wherein the metal-halide double perovskite material is Cs₂BiAgBr₆.

6. A tandem solar cell comprising first and second solar cells of different types, wherein one of the first and second solar cells includes a first solar-cell absorber layer made of a metal-halide double perovskite material and wherein the other one of the first and second solar cells includes a second solar-cell absorber layer.

7. The tandem solar cell of claim 6, wherein the first and second solar cells are mechanically stacked or monolithically integrated.

8. The tandem solar cell of claim 6, wherein the one of the first and second solar cells including the first solar-cell absorber layer further includes a glass layer and first and second transparent electrode layers.

9. The tandem solar cell of claim 6, wherein the other one of the first and second solar cells further includes an emitter layer or a transparent electrode layer, and a contact layer.

10. The tandem solar cell of claim 6, further comprising a tunnel junction/recombination layer for integrating the first and second solar-cell absorber layers.

11. The tandem solar cell of claim 6, further comprising a transparent electrode over the first solar-cell absorber layer or a contact layer under the first and second solar-cell absorber layers.

12. The tandem solar cell of claim 6, further comprising a dichroic mirror between the first and second solar cells for dividing the solar radiation spectrum between the first and second solar cells.

13. The tandem solar cell of claim 12, wherein the first solar cell further includes a glass layer, a transparent electrode layer, and a contact layer.

14. The tandem solar cell of claim 12, wherein the other one of the first and second solar cells further includes an emitter layer or a transparent electrode layer, and a contact layer.

15. The tandem solar cell of claim 6, wherein the metal-halide double perovskite material has the formula A₂BB′X₆, where A is an inorganic cation, an organic cation, or a mixture of organic and inorganic cations, where B and B′ are metals, and where X is a halide or a mixture of halides.

16. The tandem solar cell of claim 15, wherein A is Cs, Rb, K, Ba, CH₃NH₃, or (NH₂)₂CH, where B is Bi, Ag, Sn, In, Sb, Cu, Na, K, or Au of a predetermined oxidation state, where B′ is Bi, Ag, Sn, In, Sb, Cu, Na, K, Ga, or Au of various oxidation states, and where X is Br, I, Cl, or F.

17. The tandem solar cell of claim 6, wherein the metal-halide double perovskite material is Cs₂BiAgBr₆.

18. The tandem solar cell of claim 6, wherein the second solar-cell absorber layer is made of Si or CIGS.

19. The tandem solar cell of claim 6, wherein the one of the first and second solar cells including the first solar-cell absorber layer is a top solar cell and the other one of the first and second solar cells is a bottom solar cell.

20. A solar-cell absorber comprising a metal-halide double perovskite material.
